(19) United States
(12) Patent Application Publication
(10) Pub. No.: US 2008/0237446 A1
(43) Pub. Date: Oct. 2, 2008

(54) SOLID-STATE IMAGE PICKUP DEVICE AND METHOD

(75) Inventors: Hiromichi Oshikubo, Tsukuba (JP); Satoru Adachi, Tsuchiura (JP); Shunji Kashima, Moriya (JP)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/032,956

(22) Filed: Feb. 18, 2008

(30) Foreign Application Priority Data
Feb. 16, 2007 (JP) 2007-036979

(51) Int. Cl. H01L 31/062; H01L 27/00

(52) U.S. Cl. 250/208.1; 257/292; 257/E31.053

(57) ABSTRACT

A solid-state image pickup device and method are provided. The device can not only operate with a wide dynamic range but it also allows the user to switch the dynamic range corresponding to the photographic scene, and its operating method. Plural pixels, each of which has a photodiode, a transfer transistor, a floating diffusion region, an additional capacitance element, a capacitance coupling transistor, and a reset transistor, are integrated in an array on a semiconductor substrate. The capacitance of such floating diffusion region is less than that of such photodiode. A first signal S1 obtained by transferring part or all of the photoelectric charge accumulated in such photodiode PD to such floating diffusion region FD or a second signal S1+S2 obtained by transferring all of the photoelectric charge accumulated in such photodiodes to the potential obtained by coupling such floating diffusion region and such additional capacitance element CS is output to all of the pixels.

This application claims priority from Japanese Patent Application No. 2007-036979, filed 16 Feb. 2007.

### FIELD OF THE INVENTION

This relates to solid-state image pickup devices and methods.

BACKGROUND

The demand for image input image sensors, such as CMOS (complementary metal-oxide-semiconductor) image sensors or CCD (charge coupled device) image sensors, in the application fields of digital cameras and cellular phones equipped with cameras, has increased along with the performance improvement of such image sensors. Image sensors with improved performance characteristics are desired. One such characteristic is expansion of the dynamic range.

Japanese Kokai Patent Application No. 2003-134396, Japanese Kokai Patent Application No. 2000-165754, Japanese Kokai Patent Application No. 2002-77737, and Japanese Kokai Patent Application No. Hei 5[1993]-90556 disclose examples of solid-state image pickup devices designed for realizing a wide dynamic range. However, it is difficult for these solid-state image pickup devices to have a wide dynamic range while maintaining high sensitivity and a high S/N ratio.

The solid-state image pickup device disclosed in Japanese Kokai Patent Application No. 2005-328493 was developed to solve this problem. In this device, the photoelectric charge overflow from the photodiode of each pixel is accumulated in the floating diffusion region and the electrostatic capacitive element. If there is no photoelectric charge overflowing from the photodiode, the signal of each pixel is obtained by using the photoelectric charge in the photodiode. If there is photoelectric charge overflow from the photodiode, the signal of each pixel is obtained by combining the photoelectric charges in the photodiode and the photoelectric charges that have overflowed from the photodiode. However, if this solid-state image pickup device is manufactured by a CMOS process, the dark current component with respect to the photoelectric charges that have overflowed from such photodiode is large. For example, the dark current component is about 3-4 orders of magnitude greater than the required level. This is unsuitable for the accumulation of photoelectric charges over the long term and should be minimized. The dark current component is generated, for example, at the boundary directly below the gate of the transistor, or on the side surface of the element separating insulation film, or in the part in contact with the depletion layer on the silicon surface.

Examples of solid-state image pickup devices that address this problem and are designed for minimizing the dark current component and realizing a wide dynamic range, while maintaining high sensitivity and a high S/N ratio, are disclosed in International Publication No. WO 2005/083790, Japanese Kokai Patent Application No. 2005-328493, and Japanese Kokai Patent Application No. 2006-217410. However, the solid-state image pickup devices disclosed in these references are limited only to image sensors designed for a constant wide dynamic range.

It is desired to develop image sensors that are not only designed for constant wide dynamic range, but that can also switch the dynamic range as needed by the user at the imaging site.

### SUMMARY

The invention provides image sensors that are not only designed for constant wide dynamic range, but that can also switch the dynamic range as needed by the user at the imaging site.

In described embodiments, the solid-state image pickup device includes plural pixels, each of which has a photodiode that generates a photoelectric charge upon receiving light and accumulates such photoelectric charge, a transfer transistor that transfers the photoelectric charge from such photodiode, a floating diffusion region to which such photoelectric charges are transferred via such transfer transistor, an additional capacitance element that is connected to such photodiode via such floating diffusion region and accumulates the photoelectric charges transferred from such photodiode via such transfer transistor, a capacitance coupling transistor that couples or separates such floating diffusion region or such additional capacitance element, and a reset transistor that is connected to such additional capacitance element or floating diffusion region and is used to discharge the photoelectric charges in such additional capacitive element and/or such floating diffusion region, are integrated in an array on a semiconductor substrate. The capacitance of such floating diffusion region is smaller than that of such photodiode. A first signal obtained by transferring part or all of the photoelectric charges accumulated in such photodiodes in all of such pixels to such floating diffusion region or a second signal obtained by transferring all of the photoelectric charges accumulated in such photodiodes in all of such pixels to the capacitance obtained by coupling such floating diffusion region and such additional capacitance element is output as the output of such pixels.

In the described solid-state image pickup device embodiments, plural pixels, each of which has a photodiode, transfer transistor, floating diffusion region, additional capacitance element, capacitance coupling transistor, and reset transistor, are arranged in an array on a semiconductor substrate. The photodiode can generate photoelectric charges upon receiving light and can accumulate the generated photoelectric charges. The transfer transistor is used to transfer the photoelectric charges from the photodiode. The photoelectric charges are transferred to the floating diffusion region via the transfer transistor. The additional capacitance element is connected to the photodiode via the floating diffusion region and accumulates the photoelectric charges transferred from the photodiode via the transfer transistor. The capacitance coupling transistor is used to couple or separate the potentials of the floating diffusion region and the additional capacitance element. The reset transistor is connected to the additional capacitance element or the floating diffusion region to discharge the photoelectric charges in the additional capacitance element and/or the floating diffusion region.

In this case, the capacitance of the floating diffusion region is smaller than that of the photodiode. Also, a first signal obtained by transferring part or all of the photoelectric charges accumulated in such photodiodes in all of such pixels to such floating diffusion region or a second signal obtained by transferring all of the photoelectric charges accumulated in such photodiodes in all of such pixels to the capacitance obtained by coupling such floating diffusion region and such additional capacitance element is output as the output of such pixels.

Preferably, the aforementioned solid-state image pickup device of the present invention has a switch used for selecting such first signal or second signal as the output of such pixels.

Preferably, in such solid-state image pickup device of the present invention, such first or second signal of such pixels of two adjacent rows is output during the same horizontal blanking period as the output of such pixels. More preferably, the capacitance of such floating diffusion is smaller that that of such additional capacitance element. Preferably, in such solid-state image pickup device of the present invention, such first or second signal is read twice from one such pixel, the obtained two first or second signals are added or their average is calculated, and the result is output as the output of such pixels. Preferably, in such solid-state image pickup device of the present invention, the sum of the capacitance of such floating diffusion region and the capacitance of such additional capacitance element is larger than the capacitance of such photodiode. Preferably, in such solid-state image pickup device of the present invention, the capacitance of such floating diffusion region is smaller than that of such additional capacitance element. Preferably, in such solid-state image pickup device of the present invention, such pixel also has an amplifier transistor whose gate electrode is connected to such floating diffusion region and a selection transistor used for selecting such pixel connected in series with such amplifier transistor.

An embodiment of solid-state image pickup device operating method is disclosed in the form of the operating method of a solid-state image pickup device having the following configuration: plural pixels, each of which has a photodiode that generates a photoelectric charge upon receiving light and accumulates such photoelectric charge, a transfer transistor that transfers the photoelectric charge from such photodiode, a floating diffusion region to which such photoelectric charges are transferred via such transfer transistor, an additional capacitance element that is connected to such photodiode via such floating diffusion region and accumulates the photoelectric charges transferred from such photodiode via such transfer transistor, a capacitance coupling transistor that couples or separates such floating diffusion region or such additional capacitance element, and a reset transistor that is connected to such additional capacitance element or floating diffusion region and is used to discharge the photoelectric charge in such additional capacitive element and/or such floating diffusion region, are integrated in an array on a semiconductor substrate; the capacitance of such floating diffusion region is smaller than that of such photodiode. This method includes a step in which the photoelectric charge generated by such photodiode when it receives light is accumulated in such photodiode during the accumulation period and a step in which a first signal obtained by transferring part or all of the photoelectric charges accumulated in such photodiodes in all of such pixels to such floating diffusion region or a second signal obtained by transferring all of the photoelectric charges accumulated in such photodiodes in all of such pixels to the capacitance obtained by coupling such floating diffusion region and such additional capacitance element is output as the output of such pixels. In the step of obtaining such first or second signal as the output of such pixels, such first or second signal is obtained for all of such pixels.

The disclosed embodiment is the operating method of a solid-state image pickup device having the following configuration: plural pixels, each of which has a photodiode that generates a photoelectric charge upon receiving light and accumulates such photoelectric charge, a transfer transistor that transfers the photoelectric charge from such photodiode, a floating diffusion region to which such photoelectric charges are transferred via such transfer transistor, an additional capacitance element that is connected to such photodiode via such floating diffusion region and accumulates the photoelectric charge transferred from such photodiode via such transfer transistor, a capacitance coupling transistor that couples or separates such floating diffusion region or such additional capacitance element, and a reset transistor that is connected to such additional capacitance element or floating diffusion region and is used to discharge the photoelectric charge in such additional capacitive element and/or such floating diffusion region, are integrated in an array on a semiconductor substrate; the capacitance of such floating diffusion region is smaller than that of such photodiode.

First, the photoelectric charge generated by such photodiode when it receives light is accumulated in such photodiode during the accumulation period. Then, a first signal obtained by transferring part or all of the photoelectric charges accumulated in such photodiodes in all of such pixels to such floating diffusion region or a second signal obtained by transferring all of the photoelectric charges accumulated in such photodiodes in all of such pixels to the capacitance obtained by coupling such floating diffusion region and such additional capacitance element is output as the output of such pixels. In the step of obtaining such first or second signal as the output of such pixels, such first or second signal is obtained for all of such pixels. In the aforementioned solid-state image pickup device operating method disclosed in the present invention, preferably, in the step of obtaining such first or second signal as the output of such pixels, such first or second signal is obtained corresponding to a switch used for selecting either such first signal or second signal. Preferably, in the step of obtaining such first or second signal as the output of such pixels, such first or second signal of such pixels of two adjacent rows is output during the same horizontal blanking period as the output of such pixels. Preferably, in the step of obtaining such first or second signal as the output of such pixels, such first or second signal is read twice from one pixel, the obtained two first or second signals are added or their average is calculated, and the result is output as the output of such pixels.

As the first signal or second signal is output as the pixel output for all of the pixels, the disclosed solid-state image pickup device is not only suitable for a constant dynamic range but can also switch the dynamic range as demanded by the user at the imaging site. And, as the first or second signal is obtained for all of the pixels, the disclosed solid-state image pickup device operating method can not only handle a constant dynamic range, but can also switch the dynamic range as demanded by the user at the imaging site.

### BRIEF DESCRIPTION OF THE DRAWINGS

Example embodiments of the principles of the invention are given below with reference to the accompanying drawings, wherein:

FIG. 1 is an equivalent circuit diagram of one pixel (pixel) PX of a CMOS image sensor implementation according to a first embodiment example implementation of the invention.

FIG. 2 shows an example of a layout diagram of one pixel (1 pixel) in the CMOS image sensor of the first embodiment.

FIG. 3 is a schematic cross-sectional view of a part of each pixel in the CMOS image sensor of the first embodiment, taken along line A-A′ of FIG. 2.

FIG. 4 is an equivalent circuit diagram of the overall circuit configuration of the CMOS image sensor of the first embodiment.

FIG. 5 is a schematic potential diagram relating to the photodiode, transfer transistor, floating diffusion region, capacitance coupling transistor, and additional capacitance element in the CMOS image sensor of the first embodiment.

FIG. 6 is a timing diagram illustrating the voltages applied to the driving lines of the CMOS image sensor of FIG. 4 with two levels of on/off.

FIGS. 7(A)-(H) are schematic potential diagrams corresponding to the photodiode through the additional capacitance element of the CMOS image sensor in the first embodiment.

FIGS. 8(A)-(H) are schematic potential diagrams corresponding to the photodiode through the additional capacitance element of the CMOS image sensor in the first embodiment.

FIG. 9 is a layout diagram illustrating the schematic configuration of the CMOS image sensor in the first embodiment.

FIG. 10 is a timing diagram illustrating the voltages applied to the driving lines in high sensitivity mode in the first embodiment.

FIGS. 11(A)-(E) are schematic potential diagrams corresponding to the photodiode through the additional capacitance element of the CMOS image sensor in the first embodiment.

FIG. 12 is a timing diagram illustrating the voltages applied to the driving lines in low sensitivity mode in the first embodiment.

FIGS. 13(A)-(E) are schematic potential diagrams corresponding to the photodiode through the additional capacitance element of the CMOS image sensor in the first embodiment.

FIGS. 14(A)-(B) are schematic diagrams illustrating the gain increase and noise characteristic for explaining how to realize high sensitivity and high S/N ratio in the low illuminance region in the CMOS image sensor in the first embodiment.

FIG. 15 is a layout diagram illustrating the schematic configuration of the CMOS image sensor in a second embodiment of the invention.

FIG. 16 is a layout diagram illustrating the schematic configuration of the CMOS image sensor in a third embodiment of the invention.

FIG. 17 is a timing diagram illustrating the voltages applied to the driving lines in the third embodiment.

FIG. 18 is a layout diagram illustrating the schematic configuration of the CMOS image sensor disclosed in a fourth embodiment of the present invention.

FIG. 19 is a timing diagram illustrating the voltages applied to the driving lines in the fourth embodiment.

FIG. 20 is a timing diagram illustrating the voltages applied to the driving lines in the fourth embodiment.

### DESCRIPTION OF EXAMPLE EMBODIMENTS

Described below are example embodiments of a solid-state image pickup device and method according to the principles of the invention.

### First Embodiment

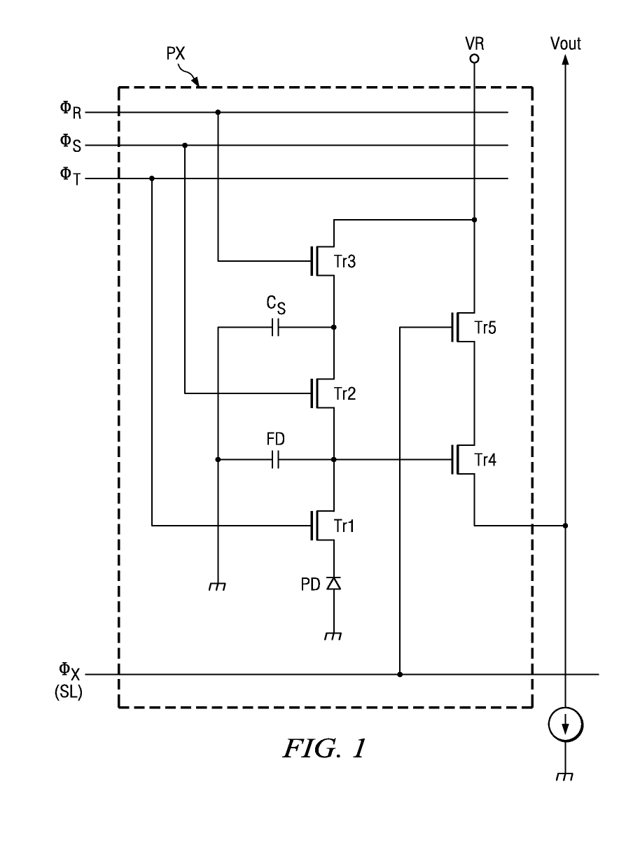

A first embodiment of solid-state image pickup device according to the invention is described with reference to FIGS. 1-14. The embodiment is a CMOS image sensor having a configuration corresponding to a wide dynamic range.

FIG. 1 shows the equivalent circuit diagram of one pixel (pixel) PX. Each pixel comprises a photodiode PD used for generating and storing photoelectric charges when receiving light, a transfer transistor Tr1 used for transferring the photoelectric charges from photodiode PD, a floating diffusion region FD to which the photoelectric charges are transferred via transfer transistor Tr1, an additional capacitance element Cs, a capacitance coupling transistor Tr2 used for coupling or separating the capacitance of floating diffusion region FD and the capacitance of additional capacitance element Cs, a reset transistor Tr3 connected to floating diffusion region FD and used for discharging the photoelectric charges in floating diffusion region FD, an amplifier transistor Tr4 (source-follower SF) having its gate connected to floating diffusion region FD and used for amplifying and converting the photoelectric charges in floating diffusion region FD into a voltage signal, and a selection transistor Tr5 connected in series with the amplifier transistor and used for selecting the pixel. The image sensor takes the general form of a so-called five-transistor type CMOS image sensor. For example, all of the five transistors are n channel MOS transistors.

The CMOS image sensor disclosed in this embodiment has plural pixels with the aforementioned configuration arranged in an array on the light receiving surface. In each pixel, the driving lines of φT, φS, φR are connected to the gate electrodes of transfer transistor Tr1, capacitance coupling transistor Tr2, and reset transistor Tr3. The pixel selecting line φX (SL), driven from the line shift register, is connected to the gate electrode of selection transistor Tr5. A prescribed voltage VR is applied to the source/drain of reset transistor Tr3 or selection transistor Tr5. Output line Vout is connected to the output side source/drain of amplifier transistor Tr4. It is controlled by the column shift register to output voltage signal. Since the voltage of floating diffusion region FD can be fixed at an appropriate value, selection transistor Tr5 and driving line φX can optionally be omitted, so that the pixel selecting or non-selecting operation becomes possible.

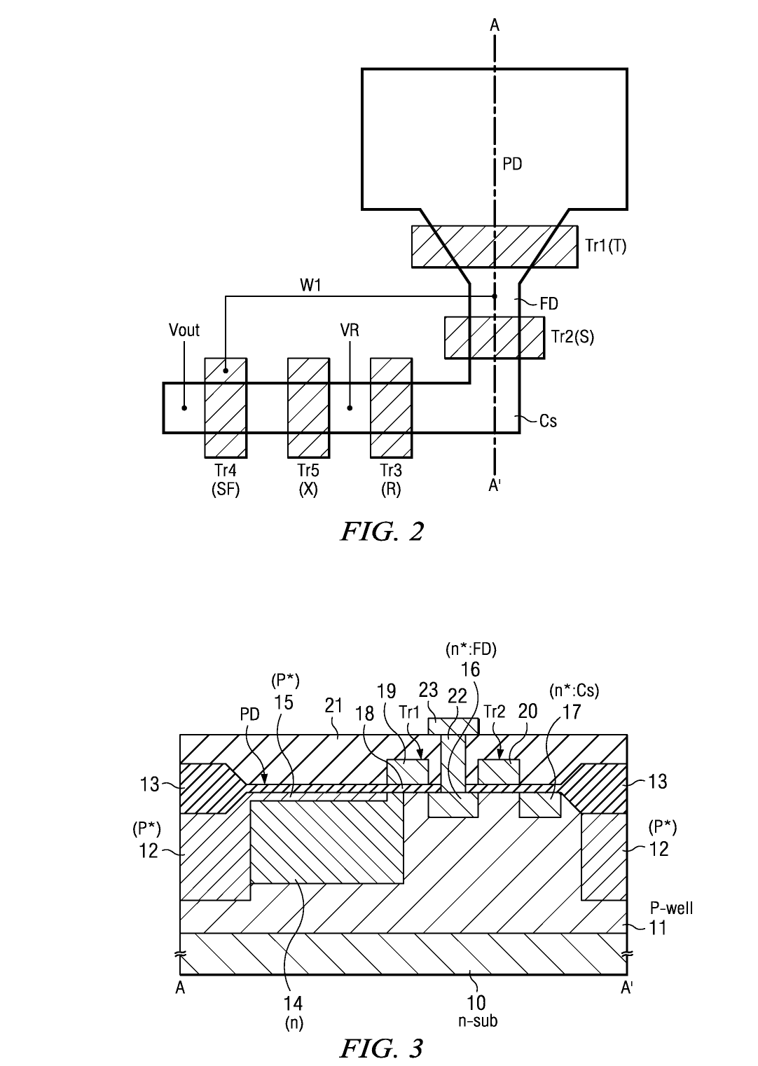

FIG. 2 shows an example of the layout diagram of one pixel (1 pixel) in the CMOS image sensor disclosed in this embodiment. Photodiode PD, additional capacitance element Cs, and five transistors Tr1-Tr5 are arranged as shown. The floating diffusion region FD between transfer transistor Tr1 (T) and capacitance coupling transistor Tr2 (S) is connected by a wire or conductor line W1 to the gate of amplifier transistor Tr4 (source follower SF). A prescribed voltage VR is connected via a wire or conductor line to the diffused layer between reset transistor Tr3 (R) and selection transistor Tr5 (X). In this way, the circuit equivalent to the equivalent circuit diagram of this embodiment shown in FIG. 1 can be realized.

In this layout, the width of the channel of transfer transistor Tr1 is wide on the side of photodiode PD and is reduced on the side of floating diffusion region FD. In this way, the photoelectric charges can be transferred from the photodiode to the floating diffusion region without delay. On the other hand, when the channel width is reduced on the side of floating diffusion region FD, the capacitance of floating diffusion region FD can be reduced, and the variation of the potential with respect to the charges accumulated in floating diffusion region FD can be increased.

For the CMOS image sensor disclosed in this embodiment having the aforementioned configuration, the capacitance CFD of floating diffusion region is smaller than the capacitance CPD of photodiode PD. That is, equation 1 below is satisfied. Preferably, the sum of the capacitance CFD of floating diffusion region FD and the capacitance CS of the additional capacitance element is greater than or equal to the capacitance CPD of photodiode PD. That is, equation 2 listed below is satisfied. Also, preferably, the capacitance CFD of floating diffusion region FD is smaller than the capacitance CS of additional capacitance element. That is, equation 3 listed below is satisfied.

CFD<CPD (1)

CFD+CS≧CPD (2)

CFD<CS (3)

In this embodiment, for example, the additional capacitance element is formed by the capacitance of the impurity diffused layer formed in the semiconductor substrate. Sufficient capacitance can be ensured even if the configuration having a pair of electrodes arranged opposite to each other via an insulating film is not adopted for the additional capacitance element. Of course, it is also possible to adopt the configuration having a pair of electrodes arranged opposite to each other via an insulating film.

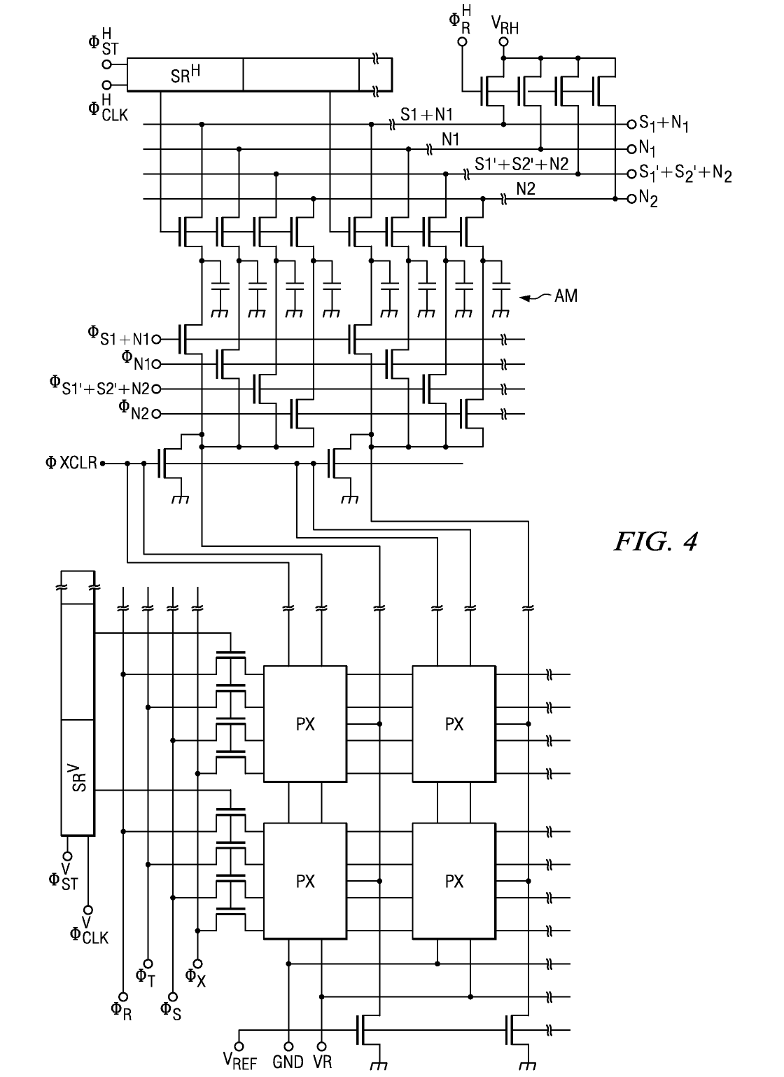

FIG. 3 is a schematic cross-sectional view illustrating part of each pixel in the CMOS image sensor (photodiode PD, transfer transistor Tr1, floating diffusion region FD, capacitance coupling transistor Tr2, and additional capacitance element Cs). For example, p-type well (p-well) 11 is formed in n-type silicon semiconductor substrate (n-sub) 10. Each pixel and additional capacitance element Cs region, etc., are divided by p⁺-type separating region 12 and element separation insulating film 13 formed using the LOCOS method, etc. N-type semiconductor region 14 is formed in p-type well 11. P⁺-type semiconductor region 15 is formed in its surface layer. A charge transfer embedded type photodiode PD is formed by the pn junction.

There is a region projecting from p⁺-type semiconductor region 15 formed in the end part of n-type semiconductor region 14. N⁺-type semiconductor region 16 acting as floating diffusion region FD is formed in the surface layer of p-type well 11 at a prescribed distance away from such region. Also, n⁺-type semiconductor region 17 acting as the additional capacitance element Cs is formed in the surface layer of p-type well 11 at a prescribed distance away from such region. Gate electrode 19 made of polysilicon is formed via a gate insulating film 18 made of silicon oxide is formed on the top surface of p-type well 11 in the area of n-type semiconductor region 14 and n⁺-type semiconductor region 16. N-type semiconductor region 14 and n⁺-type semiconductor region 16 are used as source/drain to form a transfer transistor Tr1 having a channel forming region in the surface layer of p-type well 11.

Gate electrode 20 made of polysilicon is formed via gate insulating film 18 made of silicon oxide is formed on the top surface of p-type well 11 in the area of n⁺-type semiconductor region 16 and n⁺-type semiconductor region 17. N⁺-type semiconductor region 16 and n⁺-type semiconductor region 17 are used to form capacitance coupling transistor Tr2 having a channel forming region in the surface layer of p-type well 11. An insulating film 21 made of silicon oxide is formed to cover transfer transistor Tr1, capacitance coupling transistor Tr2, and additional capacitance element Cs. An opening part is formed in each n⁺-type semiconductor region 16. Plug 22 is buried, and upper wiring 23 is formed thereon. Upper wiring 23 is connected to the gate electrode (not shown in the figure) of amplifier transistor Tr4 in a region not shown in the figure. Driving line φT is formed to connect to the gate electrode 19 of transfer transistor Tr1. Driving line φs is formed to connect to the gate electrode 20 of capacitance coupling transistor Tr2. Reset transistor Tr3, amplifier transistor Tr4, selection transistor Tr5, various driving lines (φT, φS, φR, φX) and an output line out are formed in regions not shown in the figure on semiconductor substrate 10 shown in FIG. 3, as in the configuration shown in the equivalent circuit diagram of FIG. 1.

The circuit configuration of the entire CMOS image sensor, in which the pixels with the aforementioned configuration are integrated in an array, is now described.

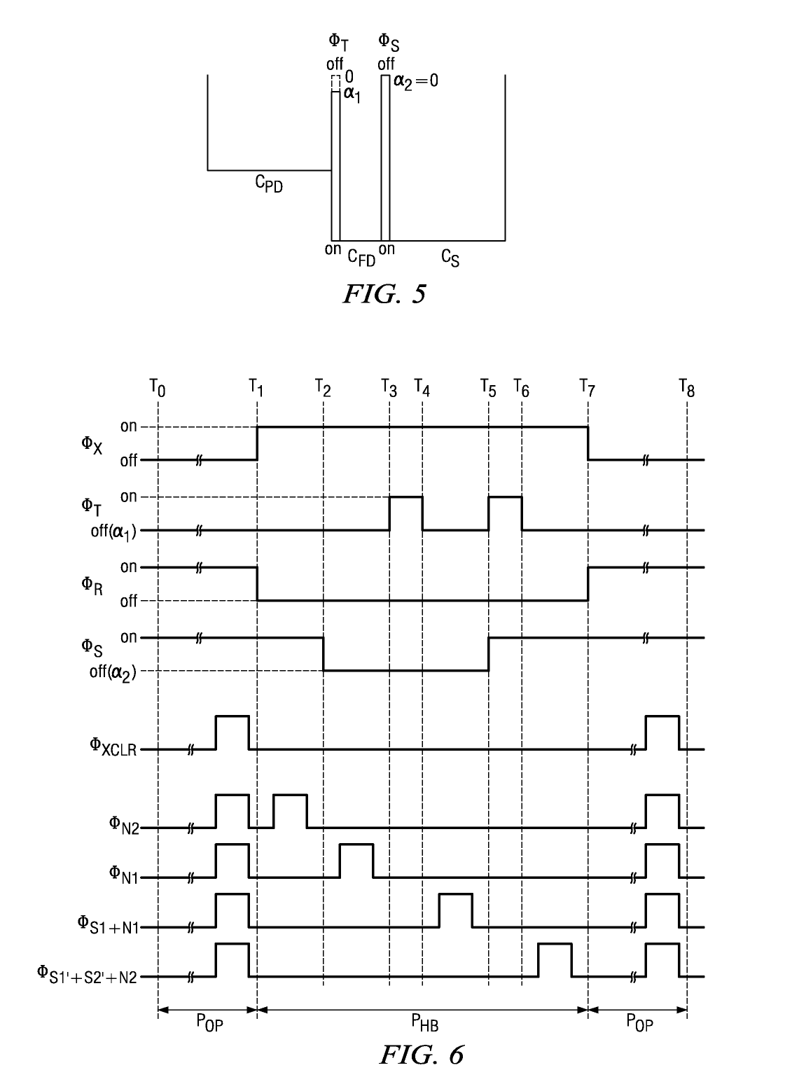

FIG. 4 is the equivalent circuit diagram illustrating the circuit configuration of the entire CMOS image sensor in this embodiment.

Plural pixels (4 pixels in the figure) Px are arranged in an array. Driving lines ((φT, φS, φR, φX) controlled by row shift transistor SRv, power supply voltage VR, and ground GND are connected to each pixel PX. Each pixel PX is controlled by column shift register SRH and driving lines (φS1+N1, φN1, φS1+S2″+N2, φN2). As will be described below, pre-saturated charge signal (S1)+CFD noise (N1), CFD noise (N1), modulated pre-saturated charge signal (S1′)+modulated supersaturated charge signal (S2′)+CFD+CS noise (N2) and CFD+CS noise (N2) are output to the output line at respective timings from each pixel PX via analog memory AM formed appropriately so that it can be cleared by driving line φXCLR.

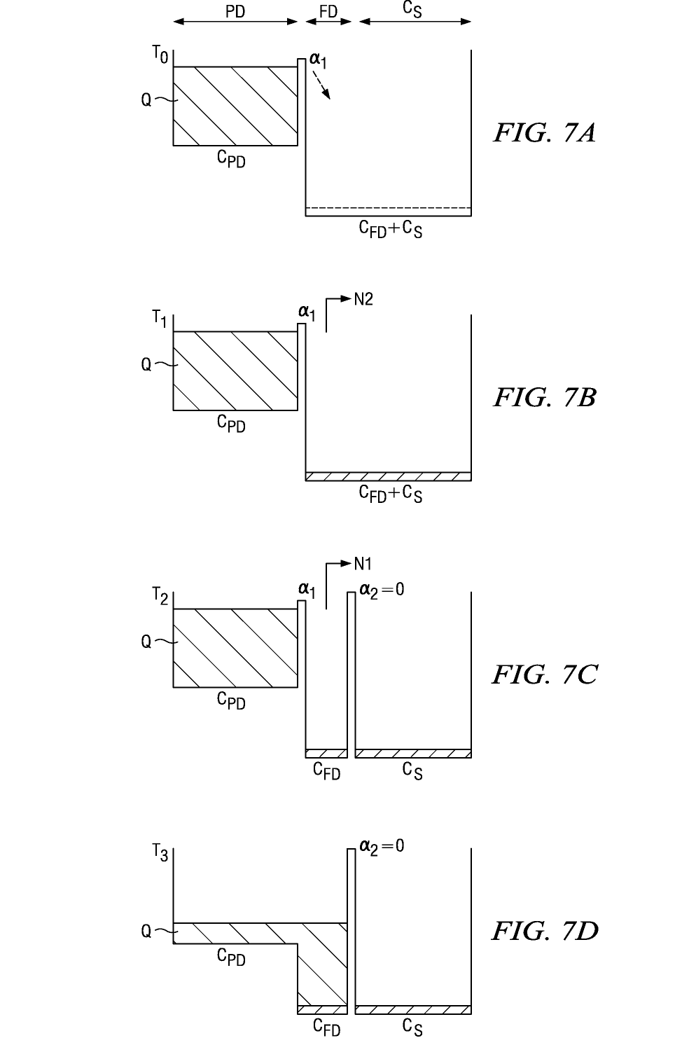

FIG. 5 shows the schematic potential diagram equivalent to such photodiode PD, transfer transistor Tr1, floating diffusion region FD, capacitance coupling transistor Tr2, and additional capacitance element Cs. Photodiode PD forms capacitance CPD with relatively shallow potential level. Floating diffusion region FD and additional capacitance element Cs form. capacitances (CFD, Cs) with relatively deep potential level. In this case, transfer transistor Tr1 and capacitance coupling transistor Tr2 take two levels corresponding to on/off of the transistors depending on φT and φS. For example, a prescribed voltage α1 is applied as the off potential of transfer transistor Tr1 with respect to the voltage applied to semiconductor substrate in consideration of the overflow from photodiode PD to floating diffusion region FD. Also, for example, a prescribed α2 (=0V) is applied as the off potential of capacitance coupling transistor Tr2. It is also possible obtain the high potential by applying the same voltage for α1 and α2.

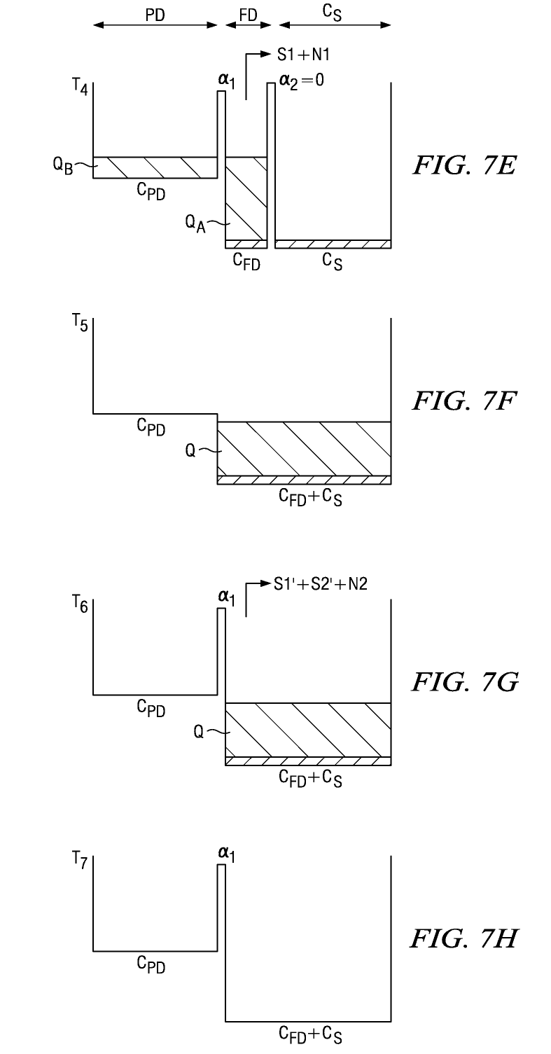

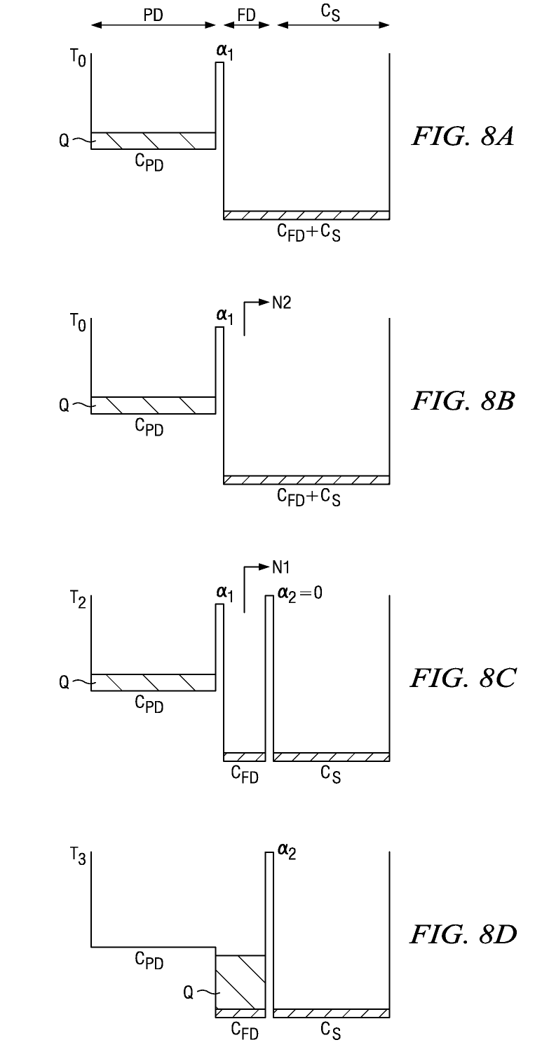

The operation method corresponding to the wide dynamic range of the CMOS image sensor disclosed in this embodiment is explained based on the equivalent circuit diagram of FIG. 1 and the potential diagram of FIG. 5. FIG. 6 is a timing diagram illustrating the voltages applied to the driving lines (φT, φS, φR, φX) and the voltages applied to driving line φXCLR and driving lines (φS1+N1, φN1, φS1′+S2′+N2, φN2) with two levels of on/off. It will be explained how to control the potential shown in FIG. 5 based on the timing diagram shown in FIG. 6. FIGS. 7(A)-(H) are equivalent to the various timings of the timing diagram.

First, photoelectric charges Q are accumulated in CPD during the accumulation period in one field. As shown in FIG. 7(A), during the accumulation period, φS and φR are on, CFD and CS are coupled, and power supply voltage VR is applied. Since φT becomes α1 level, the photoelectric charges overflowing from CPD during the accumulation period are discharged by power supply voltage VR to the potential formed by CFD+CS. Then, at the time immediately after the output period POP of the previous line is ended, at the same time when driving lines (φS1+N1, φN1, φS1′+S2′+N2, φN2) are turned on, driving line φXCLR is turned on to clear analog memory AM shown in FIG. 4.

Next, as shown in FIG. 7(B), at the time T1 when the output period POP of the previous line is ended and the horizontal blanking period PHB of that line is started, φX is turned on and φR is turned off. When φR is turned off, the so-called kTC noise is generated in the potential formed by CFD+CS. At that time, the φN2 in FIG. 4 is turned on, and the signal of the reset level of such CFD+CS is read out as noise N2.

Next, at time T2, as shown in FIG. 7(C), φS is turned off (α2). When φS is turned off, the potential formed by CFD+CS is divided into the potentials of CFD and CS. At that time, the φN1 in FIG. 4 is turned on, and the signal of the reset level of such CFD is read out as noise N1.

Then, at time T3, as shown in FIG. 7(D), φT is turned on, and part or all of the photoelectric charges Q accumulated in CPD are transferred to CFD. In this embodiment, since. CFD<CPD is designed as described above, the capacitance of CFD may be exceeded by all of the accumulated photoelectric charges. FIG. 7(D) shows the case when the photoelectric charges Q accumulated in CPD exceed CFD. Consequently, part of the photoelectric charges Q instead of all of such charges are transferred, while the rest of the photoelectric charges are left in CPD.

Next, at time T4, as shown in FIG. 7(E), in the state when the rest of the photoelectric charges are left in CFD, φT is turned off again (α1). In this way, photoelectric charges Q are divided into QA transferred to CFD and QB left in CPD. At that time, the φS1+N1 in FIG. 4 is turned on, and signal S1 corresponding to photoelectric charges QA transferred to CFD is read out as the first signal. The signal read out at the time is also known as pre-saturated charge signal since it is used as the output of that pixel in the case when the amount of all of the photoelectric charges does not saturate CFD, as will be described below. In FIG. 7(E), however, CFD is saturated by all of the photoelectric charges. Also, in the case described above, part of photoelectric charges QA and the charges corresponding to noise N1 are present in CFD. The signal that is actually read becomes S1+N1.

Then, at time T5, as shown in FIG. 7(F), φS is turned on, and φT is turned on. In this way, CFD and CS are coupled, and all of the photoelectric charges Q accumulated in CPD are transferred to CFD+CS. In this embodiment, since CFD+CS≧CPD is designed as described above, even if all of the accumulated photoelectric charges are transferred, they can be transferred without overflowing CFD+CS. Also, since CPD has shallower potential level than CFD+CS and the level of the transfer transistor is deeper than that of CPD, all of the photoelectric charges Q in CPD can be transferred to CFD+CS.

Then, at time T6, as shown in. FIG. 7(G), φT is turned off again (α1). At that time, φS1′+S2′+N2 in FIG. 4 is turned on, and signal S1+S2 corresponding to all of photoelectric charges Q transferred to CFD+CS is read out as the second signal. The signal read out at that time is expressed as signal S1+S2, in which supersaturated charge signal S2 is the signal of the part exceeding CFD with respect to pre-saturated charge signal S1. In this case, however, since there is CFD+CS noise and the signal is read from the charges in CFD+CS, the signal that is actually read becomes S1′+S2′+N2 (S1′ and S2′ are the values of S1 and S2 modulated by being reduced depending on the capacitance ratio of CFD and CS, respectively).

Then, at time T7 when horizontal blanking period PHB of that line is ended, as shown in FIG. 7(H), φX is turned off, φR is turned on to discharge the photoelectric charges at the potential formed by CFD+CS. The output period POP of that line is from time T7, when the horizontal blanking period PHB ends, to time T8. During that period, pre-saturated charge signal (S1)+CFD noise (N1), CFD noise (N1), modulated pre-saturated charge signal. (S1′)+modulated supersaturated charge signal (S2′)+CFD+CS noise (N2), and CFD+CS noise (N2) are output to the output line at respective timings.

The operation described with reference to FIGS. 7(A)-(H) is for a case in which the photoelectric charges Q accumulated in CPD exceed CFD, as described above. When the photoelectric charges Q accumulated in CPD do not exceed CFD, the signals are output as follows:

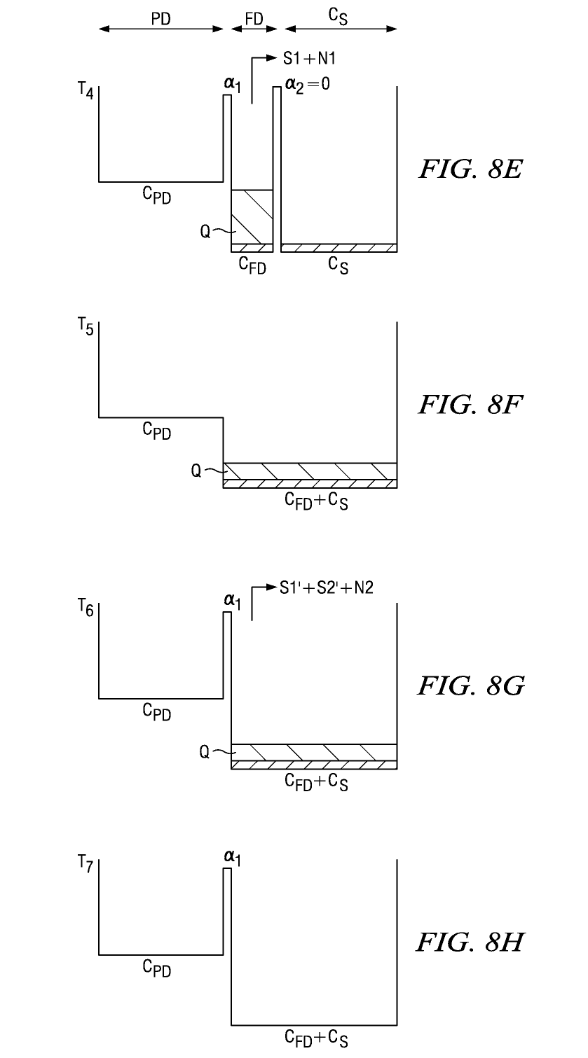

FIGS. 8(A)-(H) show the potential diagrams at various timings in the timing diagram when the photoelectric charges Q accumulated in CPD do not exceed CFD.

First, photoelectric charges Q are accumulated in CPD during the accumulation period in one field. As shown in FIG. 8(A), φX is turned off, φT is turned off (α₁), φS is turned on, and φR is turned on to discharge the photoelectric charges at the potential formed by CFD+CS.

Then, at the time immediately after the output period POP of the previous line is ended, after analog memory AM shown in FIG. 4 is cleared, as shown in FIG. 8(B), at time T1, φX is turned on, φR is turned off, and the signal of reset level of CFD+CS is read as noise N2.

Then, at time T2, as shown in FIG. 8(C), φS is turned off (α2), and the signal of the reset level of CFD is read as noise N1.

Then, at time T3, as shown in FIG. 8(D), φT is turned on, and all of the photoelectric charges Q accumulated in CPD are transferred to CFD. In this case, since the photoelectric charges Q accumulated in CPD do not exceed CFD as described above, all of photoelectric charges Q are transferred to CFD.

Then, at time T4, as shown in FIG. 8(E), φT is turned off again (α1), and pre-saturated charge signal S1 corresponding to all of the photoelectric charges transferred to CFD is read out as the first signal. As described above, the signal that is actually read is S1+N1.

Then, at time T5, as shown in FIG. 8(F), φS is turned on and φT is turned on. As a result, CFD and CS are coupled.

Then, at time T6, as shown in FIG. 8(G), φT is turned off again (α1), and signal S1+S2 corresponding to all of photoelectric charges Q transferred to CFD+CS is read out as the second signal. However, the signal that is actually read becomes S1′+S2′+N2 (S1′ and S2′ are the values of S1 and S2 modulated by being reduced depending on the capacitance ratio of CFD and CS, respectively).

Then, at time T7, as shown in FIG. 8(H), φX is turned off, and φR is turned on to discharge the photoelectric charges at the potential formed by CFD+CS.

As described above, whether or not the photoelectric charges Q accumulated in CPD exceed CFD, pre-saturated charge signal (S1)+CFD noise (N1), CFD noise (N1), modulated pre-saturated charge signal (S1′)+modulated supersaturated charge signal (S2′)+CFD+CS noise (N2), and CFD+CS noise (N2) will be read out, and the output of that pixel will be obtained as described below from each signal. That is, pre-saturated charge signal (S1)+CFD noise (N1) and CFD noise (N1) are input to a differential amplifier, which calculates the difference to cancel out CFD noise (N1) and obtain pre-saturated charge signal (S1). On the other hand, modulated pre-saturated charge signal (S1′)+modulated supersaturated charge signal (S2′)+CFD+CS noise (N2) and CFD+CS noise (N2) are input to a differential amplifier, which calculates the difference to cancel out CFD+CS noise (N2). Also, as a result of amplification, the signal is resumed depending on the capacitance ratio of CFD and CS and is adjusted to the same gain as pre-saturated charge signal (S1). In this way, the sum of pre-saturated charge signal and supersaturated charge signal (S1+S2) is obtained.

Restoration of the modulated pre-saturated charge signal (S1′)+modulated supersaturated charge signal (S2′) is described below:

S1′, S2′, α (charge distribution ratio from CFD to CFD+CS) are expressed as follows.

S1′=S1×α (4)

S2′=S2×α (5)

α=CFD/(CFD+CS) (6)

Consequently, when α is calculated from such values of CFD and CS using equation 6 and is plugged into equations 4 and 5, the signal can be restored to S1+S2 and can be adjusted to the same gain as S1 obtained separately. Then, either S1 or S1+S2 obtained as described above is selected as the final output.

In this case, for example, if the first signal (pre-saturated charge signal S1) is less than or equal to the saturation signal of floating diffusion region CFD, the first signal is used as the output of that pixel. If the first signal (pre-saturated charge signal S1) exceeds the saturation signal of floating diffusion region CFD, the second signal (pre-saturated charge signal S1+supersaturated charge signal S2) is used as the output of such pixel. To select such first signal (pre-saturated charge signal S1) or the second signal (pre-saturated charge signal S1+supersaturated charge signal S2), S1 is input to a comparator having a set reference potential, and S1 or S1+S2 is selected and output by a selector depending on the comparison result of the comparator.

For the CMOS image sensor with the aforementioned configuration, the structure up to the outputting of S1 or S1+S2 can be formed on a CMOS image sensor chip. It is also possible to form the structure up to the outputting of the signals of pre-saturated charge signal (S1)+CFD noise (N1), CFD noise (N1), modulated pre-saturated charge signal (S1′)+modulated supersaturated charge signal (S2′)+CFD+CS noise (N2) and CFD+CS noise (N2) on a CMOS image sensor chip and arrange the differential amplifier outside the chip.

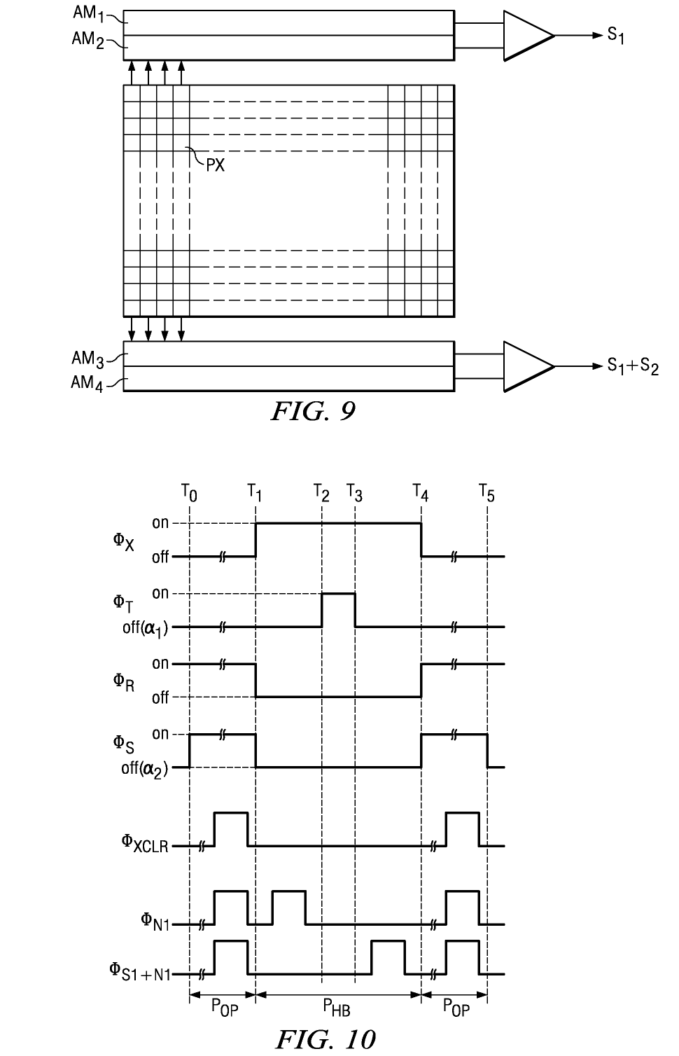

FIG. 9 is a layout diagram illustrating the schematic configuration of the CMOS image sensor disclosed in this embodiment. Plural pixels PX with the aforementioned configuration are integrated in a matrix form on the light receiving surface. The output line of each pixel PX is controlled by the driving lines (φS1+N1, φN1, φS1′+S2″+N2, φN2) shown in FIG. 4. The signals of S1+N1, N1, S1′+S2′+N2, and N2 are output via the first analog memory AM1 for pre-saturated charge signal (S1)+CFD noise (N1), the second analog memory AM2 for CFD noise (N1), the third analog memory AM3 for modulated pre-saturated charge signal (S1′)+modulated supersaturated charge signal (S2′)+CFD+CS noise (N2), and the fourth analog memory AM4 for CFD+CS noise (N2). After the aforementioned processing, the first signal (pre-saturated charge signal S1) and the second signal (pre-saturated charge signal S1+supersaturated charge signal S2) are output. The subsequent circuit compares whether S1 is smaller than the saturation signal of floating diffusion region CFD as described above, and either S1 or S1+S2 is selected and output.

In the layout shown in FIG. 9, for example, such first analog memory AM1 and second analog memory AM2 are arranged along one side of the light receiving surface, while the third analog memory AM3 and the fourth analog memory AM4 are arranged along the side opposite the light receiving surface. In this case, the CMOS image sensor of this embodiment is constituted such that the first signal (pre-saturated charge signal S1) or the second signal (pre-saturated charge signal S1+supersaturated charge signal S2) can be output for all of the pixels as the pixel output.

This is the case when the wide dynamic range mode that outputs both such first and second signals and selects one of them is the operating mode of the CMOS image sensor. It is also possible to adopt a high sensitivity mode, in which the first signal (pre-saturated charge signal S1) is output for all of the pixels, and a low sensitivity mode, in which the second signal (pre-saturated charge signal S1+supersaturated charge signal S2) is output for all of the pixels. The dynamic range modes can be switched by the user corresponding to the scene to be imaged. For example, a switch for selecting the wide dynamic range mode, the high sensitivity mode, and the low sensitivity mode can be used so that the user can select operation in any of such modes.

In the following, the operation method of the high sensitivity mode that outputs the first signal (pre-saturated charge signal S1) for all of pixels and the low sensitivity mode that outputs the second signal (pre-saturated charge signal S1+supersaturated charge signal S2) for all of the pixels will be explained. First, the high sensitivity mode will be explained.

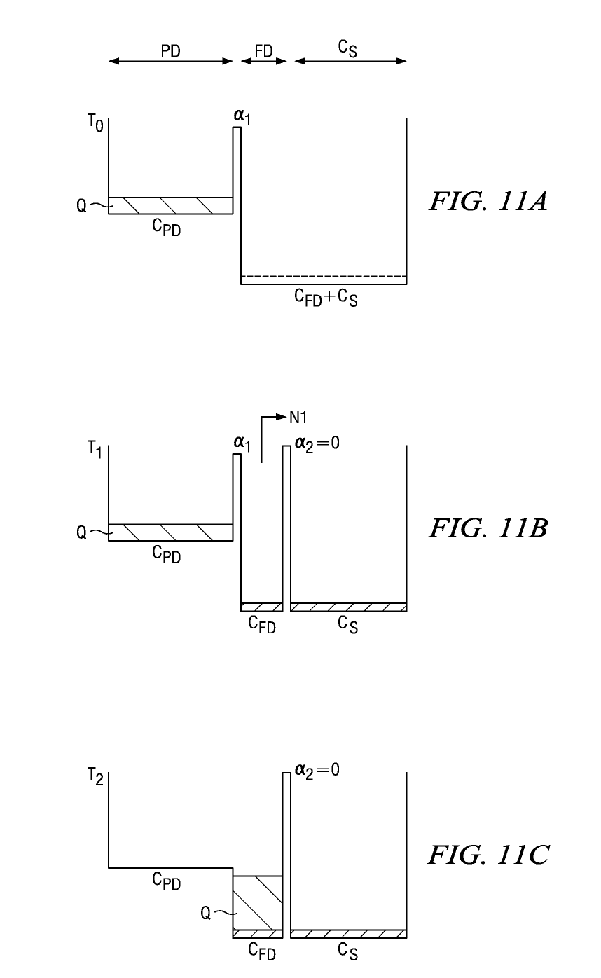

FIG. 10 is a timing diagram illustrating the voltages applied to the driving lines (φT, φS, φR, φX) and the voltages applied to such driving line φXCLR and driving lines (φS1+N1, φN1) with the two levels on/off. In the high sensitivity mode, since only the first signal S1 is output, driving lines (φS1′+S2′+N2, φN2) are not used. Consequently, since the third analog memory AM3 for S1′+S2′+N2 and the fourth analog memory AM4 for N2 shown in FIG. 9 are not used, it is acceptable that they are not cleared during the following reading operation.

How to control the potential shown in FIG. 5 is explained below based on the timing diagram shown in FIG. 10.

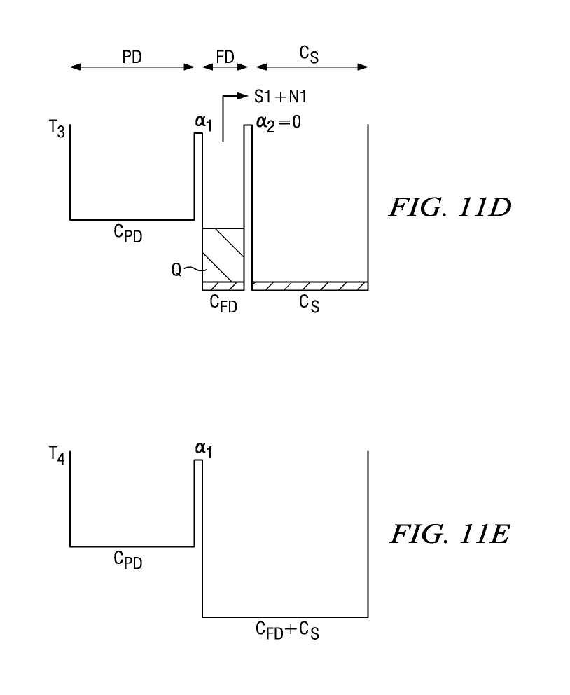

FIGS. 11 (A)-(E) are equivalent to the potential diagrams at different timings in the timing diagram.

First, photoelectric charges Q are accumulated in CPD in the accumulation period in one field. The output period POP of the previous line is set immediately before the end of the accumulation period. At time To when output period POP is started, φX is turned off, φT is turned off (α1), φS is turned on, and φR is turned on. Since φT becomes level α1, the photoelectric charges overflow from CPD during the accumulation period flow to the side of CFD. As shown in FIG. 11(A), however, at time To, φS is turned on to couple CFD and CS. φR is turned on, and the photoelectric charges in the potential formed by CFD+CS are discharged. Then, at the timing immediately before the output period POP of the previous line is ended, at the same time when driving lines (φS1+N1, φN1) are turned on, driving line φXCLR is turned on to clear the first analog memory AM1 for S1+N1 and the second analog memory AM2 for N1 shown in FIG. 9.

Then, as shown in FIG. 11(B), at time T1 when the output period POP of the previous line ends and the horizontal blanking period PHB of that line starts, φX is turned on, φR is turned off, and φS is turned off (α2). What φS is turned off (α2), the potential formed by CFD+CS is divided into the potentials of CFD and CS. When φR is turned off, so-called kTC noise is generated in the potential of CFD. In this case, the φN1 in FIG. 4 is turned on, and the signal of the reset level of such CFD is read out as noise N1.

Then, at time T2, as shown in FIG. 11(C), φT is turned on, and part or all of the photoelectric charges Q accumulated in CPD are transferred to CFD. In this embodiment, since CFD<CPD is designed as described above, the amount of all of the accumulated photoelectric charges may exceed the capacitance of CFD. FIG. 11(C) shows the case in which the amount of photoelectric charges Q accumulated in CPD is less than CFD, and all of photoelectric charges Q are transferred.

Then, at time T3, as shown in FIG. 11(D), φT is turned off again (α1). At that time, φS1+N1 in FIG. 4 is turned on, and signal S1 corresponding to photoelectric charges Q transferred to CFD is read out as the first signal. In this case, photoelectric charges Q and the charges corresponding to noise N1 are present in CFD, and the signal that is actually read is S1+N1.

Then, at time T4 when the horizontal blanking period PHB of that line ends, as shown in FIG. 11(E), φS is turned on to couple CFD and CS. In the meantime, φX is turned off, and φR is turned on to discharge the photoelectric charges in the potential formed by CFD+CS. The period from time T4 when the horizontal blanking period PHB ends until time T5 is the output period POP for that line. The signals S1+N1 and N1 output during that period as described above are output to the output line at the respective timings. As a result of such processing, the first signal S1 is output.

In the CMOS image sensor disclosed in this embodiment, in such high sensitivity mode, since the signals are read by using CFD having smaller capacitance than CPD, the sensitivity is high. However, if the photoelectric charges accumulated on CPD exceed CFD, it is unable to obtain signals corresponding to full photoelectric charges. Therefore, this is a mode corresponding to the case when the photoelectric charges Q accumulated in CPD are less than CFD. A good image suitable for the photographic object can be obtained by selecting this mode when the photographic object has low illuminance and the user image at the objects high sensitivity.

The low sensitivity mode is described as follows:

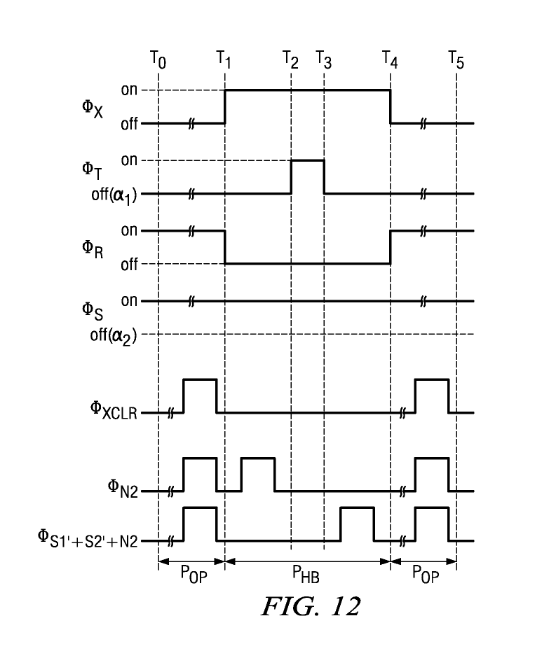

FIG. 12 is a timing diagram illustrating the voltages applied, to the driving lines (φT, φS, φR, φX) and the voltages applied to such driving line φXCLR and driving lines (φS1+N1, φN1, φS1′+S2′+N2, φN2) with two levels of on/off. In the low sensitivity mode, since only the second signal S1+S2 is output, driving lines (φS1+N1, φN1) are not used. Therefore, since the first analog memory AM1 for S1+N1 and the second analog memory AM2 for N1? shown in FIG. 9 are not used, it is acceptable that they are not cleared during the following reading operation.

The following explains how to control the potential shown in FIG. 5 based on the timing diagram shown in FIG. 12:

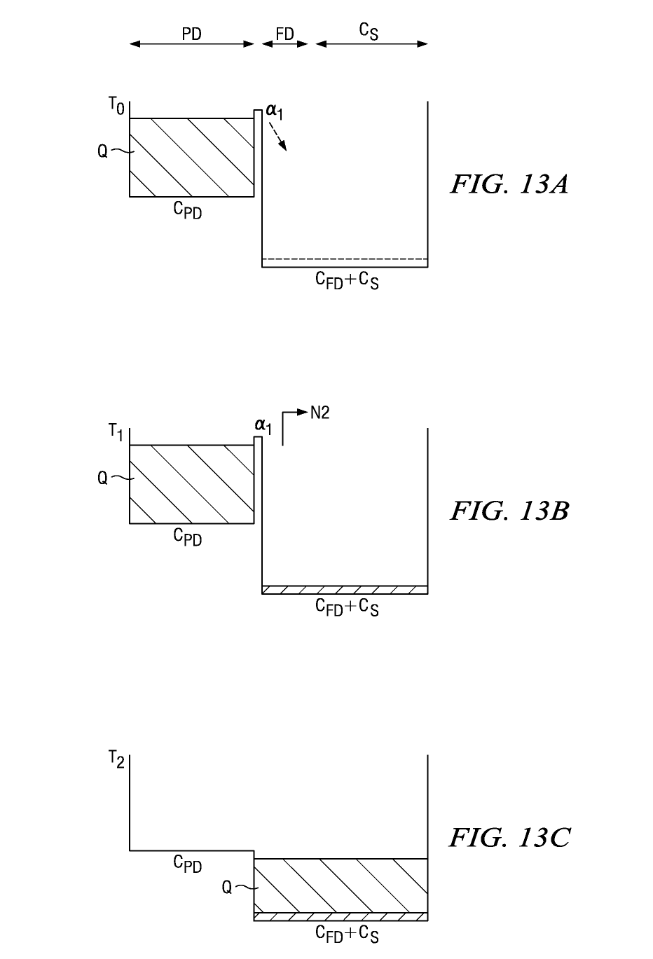

FIGS. 13(A)-(E) are equivalent to the potential diagrams at different timings in the timing diagram. First, photoelectric charges Q are accumulated in CPD in the accumulation period in one field. The output period POP of the previous line is set immediately before the end of the accumulation period. At time To when output period POP is started, φX is turned off, φT is turned off (α1), φS is turned on, and φR is turned on. After that, in the low sensitivity mode, φS is kept on all the time to couple CFD and CS. Since φT becomes level α1, the photoelectric charges that overflow from CPD during the, accumulation period flow to the side of CFD. As shown in FIG. 13(A), however, at time To, φR is turned on, and the photoelectric charges in the potential formed by CFD+CS are discharged. Then, at the timing immediately before the output period POP of the previous line is ended, at the same time when driving lines (φS1′+S2′+N2, φN2) are turned on, driving line φXCLR is turned on to clear the third analog memory AM3 for S1′+S2′+N2 and the fourth analog memory AM4 for N2 shown in FIG. 9.

Then, as shown in FIG. 13(B), at time T1 when the output period POP of the previous line ends and the horizontal blanking period PHB of that line starts, φX is turned on, and φR is turned off. When φR is turned off, so-called kTC noise is generated at the potential of CFD+CS. In this case, the φN2 in FIG. 4 is turned on, and the signal of the reset level of such CFD+CS is read out as noise N2.

Then, at time T2, as shown in FIG. 13(C), φT is turned on, and all of the photoelectric charges Q accumulated in CPD are transferred to CFD+CS. In this embodiment, since CFD+CS≧CPD is used as described above, all of the accumulated photoelectric charges can be transferred without overflowing CFD+CS. Also, since CPD has a shallower potential level then CFD+CS and the level of the transfer transistor is deeper than CPD, all of the photoelectric charges Q in CPD can be transferred to CFD+CS.

Then, at time T3, as shown in FIG. 13(D), φT is turned off again (α1). At that time, φS1′+S2′+N2 in FIG. 4 is turned on, and signal S1+S2 corresponding to all of the photoelectric charges Q transferred to CFD+CS is read out as the second signal. However, the signal that is actually read is S1′+S2′+N2 (S1′ and S2′ are the values of S1 and S2 modulated by being reduced depending on the capacitance ratio of CFD and CS, respectively).

Then, at time T4, as shown in FIG. 13(E), φX is turned off, φR is turned on, and the photoelectric charges in the potential formed by CFD+CS are discharged. The period from time T4 when the horizontal blanking period PHB ends until time T5 is the output period POP of that line. The signals of S1′+S2′+N2 and N2 output during that period as described above are output to the output line at respective timings. As a result of such processing, the second signal S1+S2 is output. Since only S1+S2 is handled in low sensitivity mode and there is no need to process signals with different gains like S1′+S2′ and S1, it is acceptable not to adjust the gain of S1′+S2′ in some cases.

In the CMOS image sensor in this embodiment, such low sensitivity mode is a mode corresponding to the case when the photoelectric charges accumulated in CPD exceed CFD. A good image suitable for the photographic object can be obtained by selecting this mode when the photographic object has a high illuminance and the user images the object at low sensitivity.

In the CMOS image sensor in this embodiment, since the capacitance CFD of floating diffusion region FD is smaller than the capacitance CPD of photodiode PD (CFD<CPD), high sensitivity and high S/N ratio can be realized for the signal in the low illuminance region by obtaining the first signal (pre-saturated charge signal S1) by using only the signal of CFD with small capacitance. Also, since the sum of the capacitance CFD of floating diffusion region FD and the capacitance CS of the additional capacitance element is larger than the capacitance CPD of photodiode CPD (CFD+CS≧CPD), a signal can be obtained at high sensitivity not only in such low illuminance region but also in the high illuminance region corresponding to the saturation amount of capacitance CPD of photodiode PD by obtaining the second signal (pre-saturated charge signal S1+supersaturated charge signal S2) so that a wide dynamic range can be realized. In particular, when the capacitance CFD of floating diffusion region FD is set to be smaller than the capacitance CS of the additional capacitance element (CFD<CS), the sensitivity in the low illuminance region can be further improved. For example, when CFD is set to 0.4 fF so that one electron can be detected and CFD:CS is set to 1:7, a high-sensitivity signal can be obtained up to the illuminance region in which CPD is about 3-4 fF.

The CMOS image sensor disclosed in this embodiment not only can provide wide dynamic range constantly as described above but also can output the first or second signal to all of the pixels as the output of the pixels. The user can switch the dynamic range between the high sensitivity mode that outputs the first signal and the low sensitivity mode that outputs the second signal corresponding to the photographic scene.

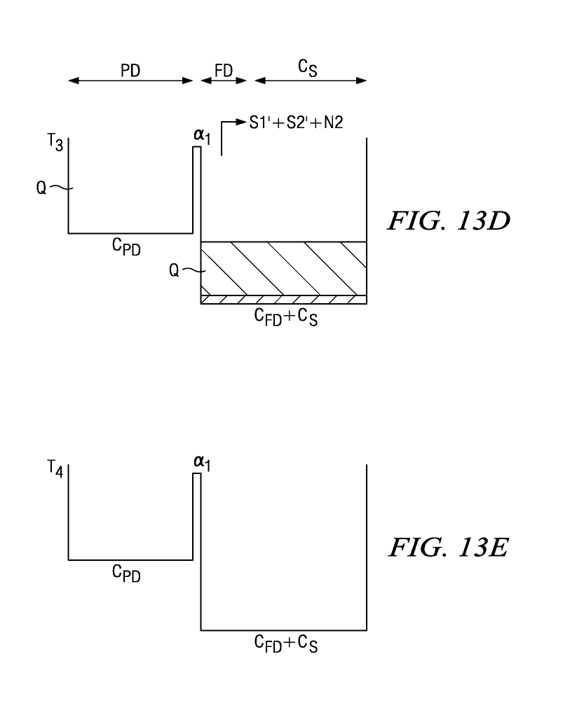

FIGS. 14A) and (B) are schematic diagrams illustrating the gain increase and noise characteristic for explaining how to realize high sensitivity and high S/N ratio in the low illuminance region in the CMOS image sensor disclosed in this embodiment. The abscissa is the incident light quantity L, while the ordinate is output OP. FIG. 14(A) shows the gain increase and noise characteristic of a conventional CMOS image sensor. The noise Na at the level of baseline noise BN rides on the basic output a. When the basic output a is electrically amplified in the low-illuminance region by an amplifier arranged in the stage after the output, an output b with increased gain is obtained. The noise signal becomes noise Nb obtained by amplifying noise Na. On the other hand, FIG. 14B shows the gain increase and noise characteristic of the CMOS image sensor disclosed in this embodiment. In low sensitivity mode, output c of the second signal (pre-saturated charge signal S1+supersaturated charge signal S2) corresponding to high illuminance is obtained. In high sensitivity mode, output d of the first signal (pre-saturated charge signal S1) that can improve the sensitivity in the low illuminance region is obtained. Noise Nc, Nd at the level of baseline noise BN ride on such signals. However, since the noise Nd of output d of the first signal (pre-saturated charge signal S1) is not obtained by amplifying noise Nc, high sensitivity and a high S/N ratio can be realized for the signal corresponding to the low illuminance region.

### Second Embodiment

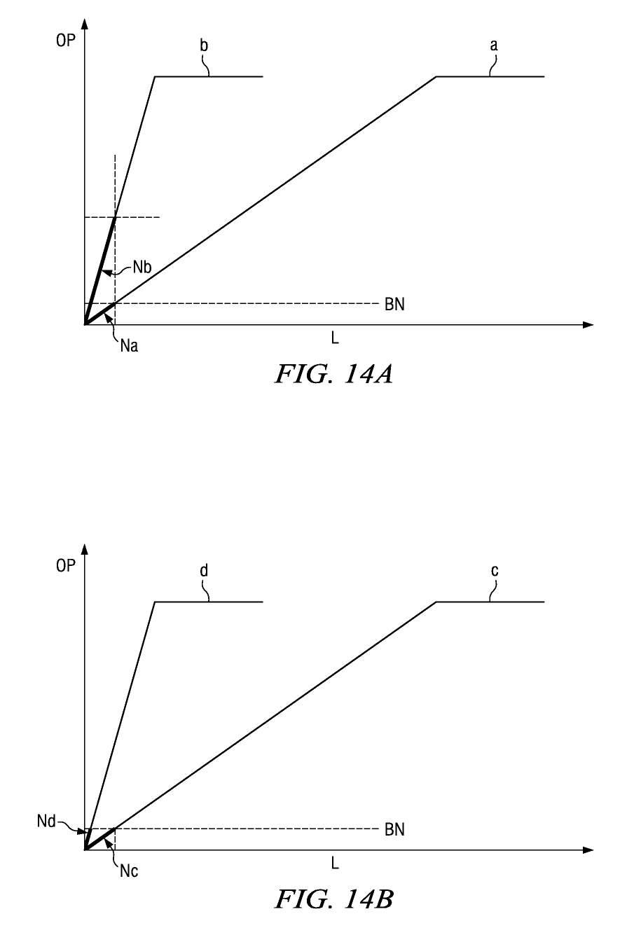

FIG. 15 is the layout diagram illustrating the schematic configuration of the CMOS image sensor according to a second embodiment. In the first embodiment, the first analog memory AM1 through the fourth analog memory AM4 are arranged near the light receiving surface. In this embodiment, however, only the first analog memory AM1 and the second analog memory AM2 are arranged. Since the CMOS image sensor disclosed in the first embodiment has a wide dynamic range mode besides the high sensitivity mode and the low sensitivity mode, it requires the first analog memory AM1 through the fourth analog memory AM4. The CMOS image sensor disclosed in this embodiment is designed to only handle the high and low sensitivity modes. It is only necessary to use such two analog memories regardless of when the image sensor operates in high sensitivity mode or low sensitivity mode. Consequently, in the high sensitivity mode, S1+N1 is handled by the first analog memory AM1, and the N1 is handled by the second analog memory AM2. On the other hand, in low sensitivity mode, S1′+S2′+N2 is handled by the first analog memory AM1, and N2 is handled by second analog memory AM2. Therefore, the third analog memory AM3 and the fourth analog memory AM4 used in the CMOS image sensor disclosed in the first embodiment can be omitted.

### Third Embodiment

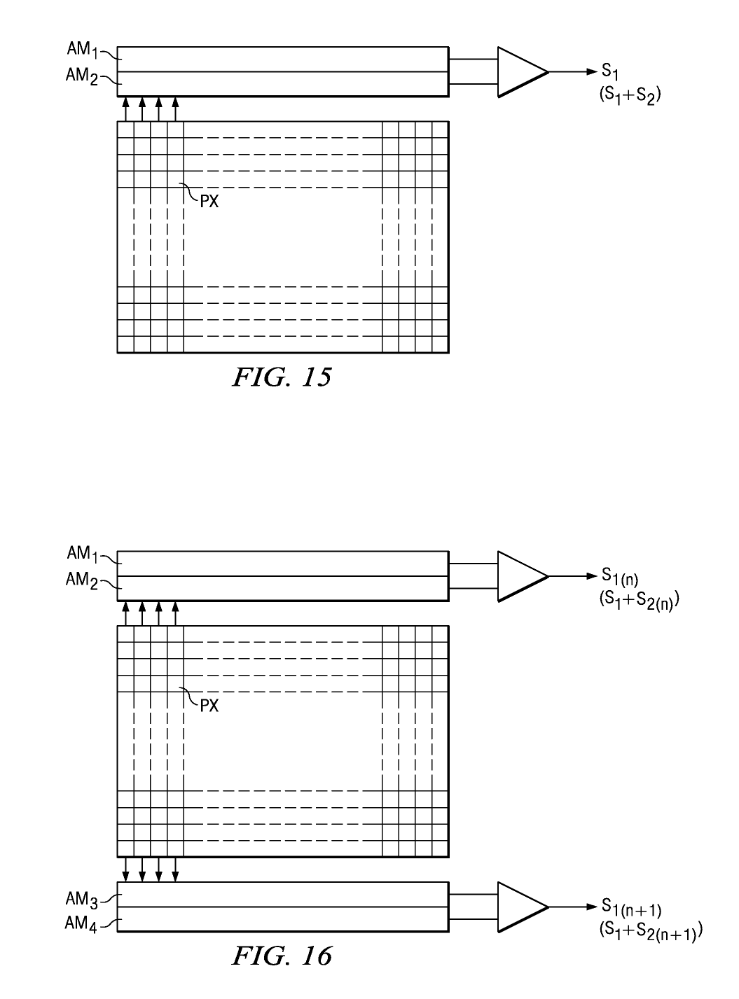

FIG. 16 is the layout diagram illustrating the schematic configuration of the CMOS image sensor according to a third embodiment. In this embodiment, four analog memories, that is, the first analog memory AM1 through the fourth analog memory AM4 are arranged near the light receiving surface in the same way as described in the first embodiment. In this case, since only two analog memories are used when the image sensor operates in high sensitivity mode or low sensitivity mode, the first or second signal of the pixels of two adjacent rows can be output during the same horizontal blanking period. For example, in high sensitivity mode, the S1+N1(n) of the pixels in the nth row is stored in the first analog memory AM1, and the N1(n) of the pixels in the .nth row is stored in the second analog memory AM2, and the first signal S1(n) is obtained after the calculation processing. Also, the S1+N1(n+1) of the pixels in the (n+1)th row is stored in the third analog memory AM3, and the N1(n+1) of the pixels in the (n+1)th row is stored in the fourth analog memory AM4, and the first signal S1(n+1) is obtained after the calculation processing.

Although the circuit configuration is the same as that of the CMOS image sensor disclosed in the first embodiment, S1+N1(n+1) of the pixels in the adjacent n+1 rows in the timing diagram is output from the output line connected to the third analog memory AM3 at the time when it is read out, and N1(n+1) of the pixels in the adjacent n+1 rows in the timing diagram is output from the output line connected to the fourth analog memory AM4 at the time when it is read out. In this way, such signals can be obtained. When the obtained first signal Sn(n) and the first signal Sn(n+1) are output during the same output period, the time required for reading can be reduced. Similarly, in low sensitivity mode, S1′+S2′+N2(n) of the pixels in the nth row is stored in the first analog memory AM1, and N2(n) of the pixels in the nth row is stored in the second analog memory AM2. S1′+S2′+N2(n+1) of the pixels in the (n+1)^{th} row is stored in the third analog memory AM3, and N2(n+1) of the pixels in the (n+1)^{th} row is stored in the fourth analog memory AM4. The second signal S1+S2(n) and the second signal S1+S2(n+1) obtained from the calculation processing are output during the same output period so that the time required for reading can be reduced.

The operation method of the CMOS image sensor disclosed in this embodiment in the high sensitivity mode is explained below:

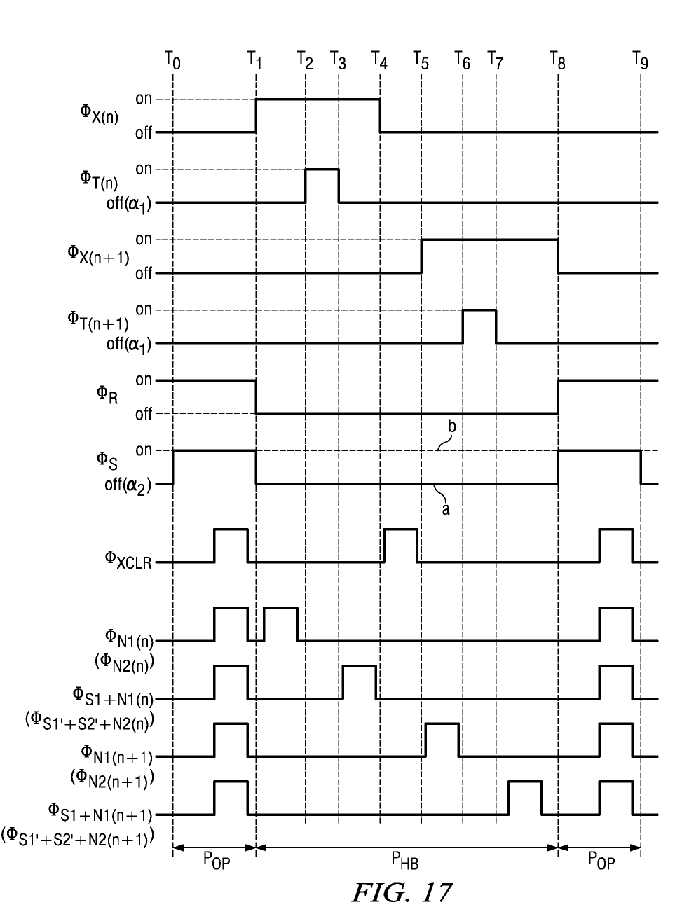

FIG. 17 is a timing diagram illustrating the voltages applied to the driving lines (φX(n), φT(n), φX(n+1), φT(n+1) φR, φS) and the voltages applied to such driving line φXCLR and driving lines (φS1+n1(n), φN1(n1), φS1+N1(n+1)), φN1(n+1)) of such nth row and (n+1)th row with two levels of on/off. In this case, the φS in the high sensitivity mode is shown as solid line a. Driving lines φS1+N1(n+1)), φN1(n+1) correspond to φS1′+S2′+N2 and φN2 in the first embodiment, respectively. The signals read out depending on the read-out timing become S1+N1(n+1) and N1(n+1), respectively.

First, photoelectric charges Q are accumulated in CPD in the accumulation period in one field. The output period POP of the previous line is set immediately before the end of the accumulation period. At time To when output period POP is started, φX(n) is turned off, φT(n) is turned off (α1), φX(n+1) is turned off, φT(n+1) is turned off (α1), φS is turned on, and φR is turned on.

Then, at the timing immediately before the output period POP of the previous line ends, at the same time when driving lines (φS1+N1(n), φN1(n), φS1+N1(n+1), and φN1(n+1)) are turned on, driving line φXCLR is turned on to clear the first analog memory AM1 through the fourth analog memory AM4.

Then, at time T1 when the output period POP of the previous line ends and the horizontal blanking period PHB of that line starts, φX(n) is turned on, φR is turned off and φS is turned off (α2). When φS is turned off (α2), the potential formed by CFD+CS is divided into the potentials of CFD and CS. When φR is turned off, so-called kTC noise is generated in the potential of CFD. In this case, φN1(n) is turned on, and the signal of the reset level of such CFD is read out as noise N1(n).

Then, at time T2, φT(n) is turned on, and the photoelectric charges accumulated in CPD of the pixels of the nth row are transferred to CFD. At time T3, φT(n) is turned off again (α1). At that time, φS1+N1(n) is turned on, and S1+N1(n) is read.

Then, at time T4, φX(n) is turned off, and then, φXCLR is turned on to clear the driving lines. At time T5, φX(n+1) is turned on.

Then, φN1(n+1) is turned on, and the signal of the reset level of that CFD is read out as N1(n+1).

Then, at time T6, φT(n+1) is turned on, and the photoelectric charges accumulated in the CPD of the pixels of the (n+1)th row are transferred to CFD. At time T7, φT(n+1) is turned off again (α1).

At that time, φS1+N1(n+1) is turned on, and S1+N1(n+1) is read out.

Then, at time T8 when the horizontal blanking period. PHB of that line ends, φS is turned on to couple CFD and CS. In the meantime, φX(n+1) is turned off, and φR is turned on to discharge the photoelectric charges in the potential formed by CFD+CS.

The period from time T8 when such horizontal blanking period PHB ends up to time T9 is the output period POP of the pixels of the nth row and the (n+1)^{th} row. The signals S1+N1(n) and N1(n), S1+N1(n+1) and N1(n+1) output as described in such period are output to the output line at respective timings. After the aforementioned calculation processing, S1(n) and S1(n+1) are output.

An operation method of the CMOS image sensor disclosed in this embodiment in the low sensitivity mode is described as follows:

In FIG. 17, φS is driven at the timing indicated by dashed line b. In this case, driving lines (φS1+N1(n), φN1(n), φS1+N1(n+1), φN1(n+1)) correspond to driving lines (φS1′+S2′+N2(n)), φN2(n), φS1′+S2′+N2(n+1), φN2(n+1)), respectively. Signals S1′+S2′+N2(n), N2(n), S1′+S2′+N2(n+1), N2(n+1) are output to the output lines at respective timings under driving performed according to the timing diagram shown in FIG. 17. After the aforementioned calculation processing, S1+S2(n) and S1+S2(n+1) are output. In the CMOS image sensor disclosed in this embodiment, the first or second signal of the pixels in two adjacent rows can be output during the same horizontal blanking period so that the time required for reading can be reduced.

### Fourth Embodiment

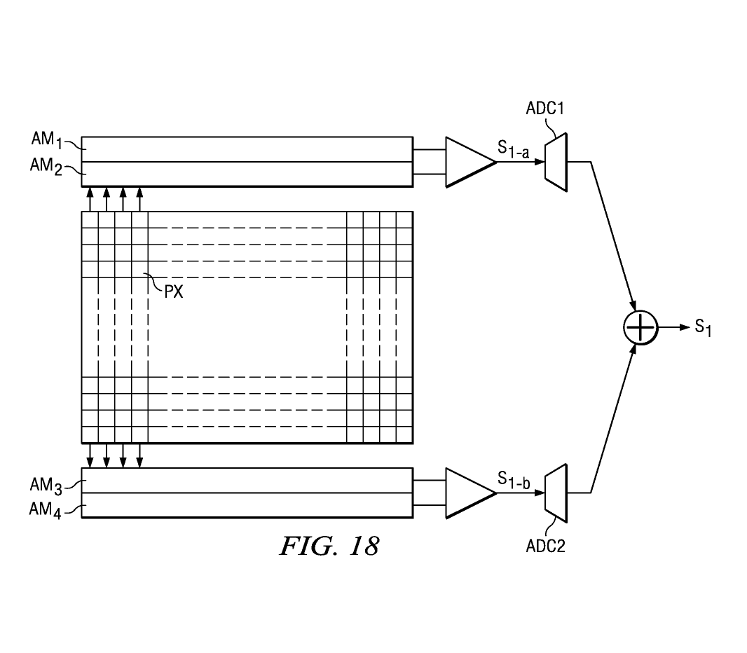

FIG. 18 is a layout diagram illustrating the schematic configuration of the CMOS image sensor according to a fourth embodiment. In this embodiment, four analog memories, that is, the first analog memory AM1 through the fourth analog memory AM4 are arranged near the light receiving surface in the same way as described in the first embodiment. In this case, only two analog memories are used when the image sensor operates in the high sensitivity mode or low sensitivity mode. The first or second signal is read out twice from one pixel as the pixel output. The obtained two first or second signals are added, or the average is calculated. Then, the result is output. For example, in high sensitivity mode, S1+N1 is stored in the first analog memory AM1, and N1 is stored in the second analog memory AM2. The first signal S1-a is obtained after the calculation processing. Also, S1+N1 of the same pixel is stored in the third analog memory AM3, and N1 is stored in the fourth analog memory AM4, and the second first signal S1-b is obtained after the calculation processing. The obtained two first signal S1-a, S1-b are digitized by A/D converters ADC1, ADC2, respectively. Then, they are added and output as the first signal S1. It is also possible to output the average value as S1.

The circuit configuration is the same as that of the CMOS image sensor disclosed in the first embodiment. In the timing diagram, however, S1+N1 is output from the output lines connected to the first and third analog memories AM1, AM3 simultaneously or separately at the timing of reading such signal, and N1 is output from the output lines connected to the second and the fourth analog memories AM2, AM4 simultaneously or separately at timing of reading such signal. In this way, such signals can be obtained. When the obtained two first signals S1 are output during the same output period, the time required for reading can be reduced.

The operation method of the CMOS image sensor disclosed in this embodiment is described as follows:

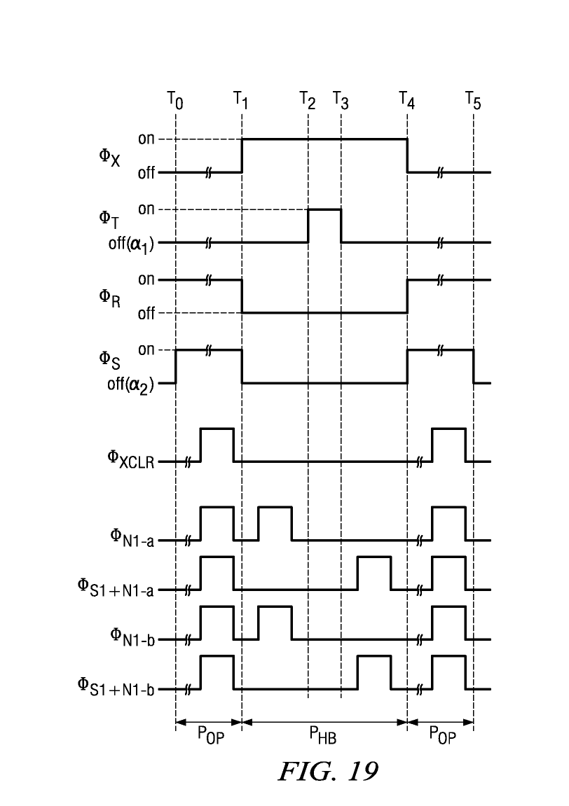

FIG. 19 is a timing diagram illustrating the voltages applied to the driving lines (φX, φT, φR, φS) and the voltages applied to such driving line φXCLR and driving lines (φS1+N1-a, φN1-a, φS1+N1-b, φN1-b) of such nth row and (n+1)^{th} row with two levels of on/off. Driving lines φS1+N1-a and φN1-a correspond to φS1+N1 and φN1 in the first embodiment, respectively. Driving lines φS1+N1-b and φN1-b correspond to the driving lines φS1′+S2′+N2 and φN2 in the first embodiment. The signals read out depending on the read-out timing become S1+N1 and N1, respectively.

First, photoelectric charges Q are accumulated in CPD during the accumulation period in one field. The output period POP of the previous line is set immediately before the end of the accumulation period. At time To when output period POP is started, φX is turned off, φT is turned off (α1), φS is turned on, and φR is turned on.

Then, at the timing immediately before the output period POP of the previous line ends, at the same time when driving lines (φS1+N1-a, φN1-a, φS1+N1-b, φN1-b) are turned on, driving line φXCLR is turned on to clear the first analog memory AM1 through the fourth analog memory AM4.

Then, at time T1 when the output period POP of the previous line ends and the horizontal blanking period PHB of that line starts, φX is turned on, φR is turned off, and φS is turned off (α2). When φS is turned off (α2), the potential formed by CFD+CS is divided into the potentials of CFD and CS. When φR is turned off, so-called kTC noise is generated at the potential of CFD. In this case, φN₁₋ₐ is turned on, and the signal of the reset level of CFD is read out as noise N₁₋ₐ In the meantime, φN1-b is turned on, and the signal of the reset level of such CFD is read out as noise N1-b.

Then, at time T2, φT is turned on, and the photoelectric charges accumulated in CPD are transferred to CFD. At time T3, φT is turned off again (α1). At that time, φS₁+N₁₋ₐ is turned on, and S₁+N₁₋ₐ is read out. In the meantime, φS1+N-b is turned on, and S₁+N_{1-b} is read out.

Then, at time T4, φX is turned off, φR is turned on, φS is turned on to discharge the photoelectric charges in the potential formed by CFD+CS.

The period from time T4 when such horizontal blanking period PHB ends to time T5 is the output period POP. The signals S1+N1-a and N1-a, S1+N1-b and N1-b output as described in such period are output to the output lines at respective timings. After the aforementioned calculation processing, S1-a and S1-b are output. They are added up or the average is calculated.

The CMOS image sensor disclosed in this embodiment can also be driven in low sensitivity mode. More specifically, the image sensor can be driven in the same way as described above except that φS is kept on constantly. The CMOS image sensor disclosed in this embodiment reads out two signals from one pixel and adds the two signals or calculates their average to obtain the pixel output. Therefore, it can help reduce noise at low illuminance. When noise N1-a and noise N1-b are read out simultaneously and S1+N1-a and S1+N1-b are read out simultaneously as described above, high-speed driving can be realized.

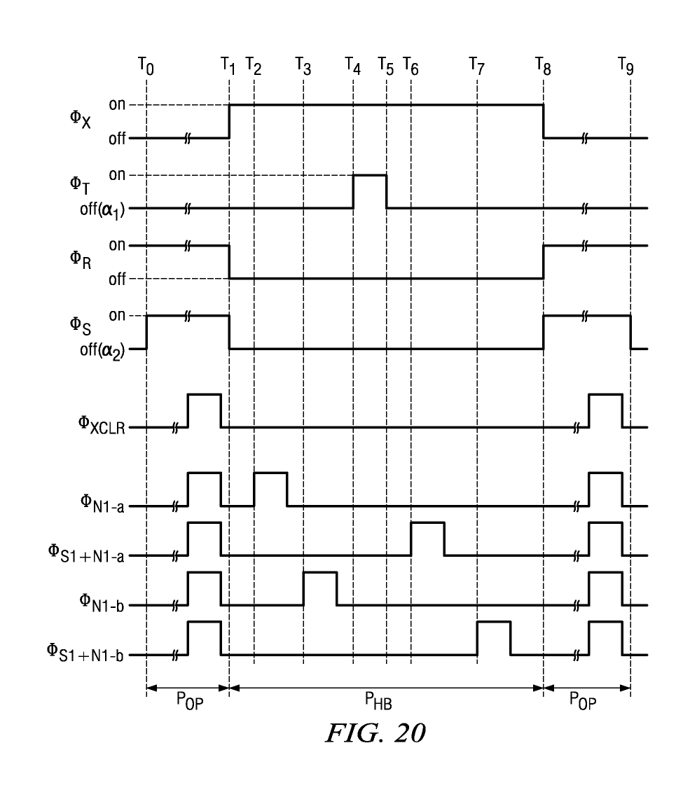

FIG. 20 shows another example of the timing diagram of the CMOS image sensor disclosed in this embodiment. Noises N1-a and N1-b are read out at different timings and S1+N1-a and S1+N1-b are also read out at different timings. In this case, although it takes a little longer to read out the signals, mixing of noise during reading can be alleviated so that high-quality signals can be obtained.

In the following, for the case of SVGA with 800×600 pixels, the horizontal blanking period (μs), number of read lines (lines), and reading speed (fps (frame per second)) of the CMOS image sensors disclosed in such first-fourth embodiments are compared with the operation characteristics in the wide dynamic range mode explained in the first embodiment. The results are shown in Table 1.

TABLE 1

| | Wide | High sensitivity/low | Third | Forth |
|---|---|---|---|---|
| | dynamic | sensitivity mode | embodi- | embodi- |
| | range mode | (first embodiment) | ment | ment |
| Horizontal | 10 | 5 | 9-10 | 5-7.5 |
| blanking period | | | | |
| Number of read | 600 | 600 | 300 | 600 |
| lines | | | | |
| Reading speed | 30 | 35 | 65-63 | 35-33 |

As shown in Table 1, in high sensitivity/low sensitivity mode of the first embodiment, the horizontal blanking period can be reduced by half compared with the wide dynamic range mode so that the reading speed can be increased.

In the third embodiment, since the number of read lines can be reduced by half compared with the wide dynamic range mode, the reading speed can be increased or even doubled.

In the fourth embodiment, the horizontal blanking period can be reduced compared with the wide dynamic range mode so that the reading speed can be increased.

As described above, the CMOS image sensor disclosed in this embodiment has the following effects.

(1) The function of the wide dynamic range CMOS image sensor having two outputs, high sensitivity and low sensitivity, can be maintained. In the meantime, by changing the driving circuit and the driving timing, the user can switch the dynamic range between the high sensitivity mode and the low sensitive mode corresponding to the photographic scene while keeping the same configuration and image quality as the conventional 4 Tr type CMOS image sensor.

(2) In a digital still camera, the low sensitivity mode can be designed to ISO100, and the high sensitivity mode can be designed to about ISO400-800. A high-quality image with less noise than the conventional 4 Tr type CMOS image sensor can be obtained.

(3) In high sensitivity mode/low sensitivity mode, since only S1 or S1+S2 is output, the driving timing can be simplified, the horizontal blanking period can be shortened, and the time for reading the entire image screen can be reduced compared with that in the wide dynamic range mode.

The present invention is not limited to the foregoing explanation. For example, the capacitance ratio between the floating diffusion region and the additional capacitance element can be varied appropriately corresponding to the design. It is also possible to use an additional capacitance element, in which two electrodes are arranged opposite to each other via an insulating film. Other modifications can also be made without departing from the scope of the claimed invention.

The solid-state image pickup device of the present invention can be used for CMOS image sensors, CCD image sensors, or other image sensors for which a wide dynamic range is desired, in digital cameras, cellular phones equipped with cameras, etc. The operation method of the solid-state image pickup device disclosed in the present invention can be used as the operation method of an image sensor for which a wide dynamic range is desired.

What is claimed is:

1. A solid-state image pickup device having a plurality of pixels integrated in an array on a semiconductor substrate; each pixel comprising:
a photodiode that generates photoelectric charge upon receiving light and accumulates such photoelectric charge;
a transfer transistor that transfers the photoelectric charge from such photodiode;
a floating diffusion region to which such photoelectric charge is transferred via such transfer transistor;
an additional capacitance element that is connected to such photodiode via such floating diffusion region and accumulates the photoelectric charge transferred from such photodiode via such transfer transistor;
a capacitance coupling transistor that couples or separates such floating diffusion region or such additional capacitance element; and
a reset transistor that is connected to such additional capacitance element or floating diffusion region and is used to discharge the photoelectric charge on such additional capacitance element and/or such floating diffusion region;
wherein the capacitance of the floating diffusion region is smaller than that of the photodiode; and
wherein a first signal obtained by transferring part or all of the photoelectric charge accumulated on the photodiodes in all of such pixels to the floating diffusion region, or a second signal obtained by transferring all of the photoelectric charge accumulated in the photodiodes in all of such pixels to the capacitance obtained by coupling the floating diffusion region and the additional capacitance element, is output as the output of the pixels.

2. The device of claim 1, further comprising a switch for selecting the first signal or second signal as the output of such pixels.

3. The device of claim 1, wherein the first or second signal of pixels in two adjacent rows is output during a same horizontal blanking period as the output of such pixels.

4. The device of claim 1, wherein the first or second signal is read twice from one such pixel; the twice read outputs are added or averaged; and the result is output as the output of such pixels.

5. The device of claim 1, wherein the sum of the capacitance of the floating diffusion region and the capacitance of the additional capacitance element is greater than the capacitance of the photodiode.

6. The device of claim 5, wherein the capacitance of the floating diffusion region is smaller than that of the additional capacitance element.

7. The device of claim 1, wherein the additional capacitance element is formed by the capacitance of an impurity diffused layer formed in the semiconductor substrate.

8. The device of claim 1, wherein the pixel further comprises an amplifier transistor having its gate electrode connected to the floating diffusion region and a selection transistor used for selecting the pixel connected in series with the amplifier transistor.

9. A method for operating a solid-state image pickup device, comprising a solid-state image pickup device including a plurality of pixels integrated in an array on a semiconductor substrate, each pixel comprising:
a photodiode that generates photoelectric charge upon receiving light and accumulates such photoelectric charge;
a transfer transistor that transfers the photoelectric charge from the photodiode;
a floating diffusion region to which the photoelectric charge is transferred via the transfer transistor;
an additional capacitance element that is connected to the photodiode via the floating diffusion region and accumulates the photoelectric charge transferred from the photodiode via the transfer transistor;
a capacitance coupling transistor that couples or decouples the floating diffusion region or the additional capacitance element; and
a reset transistor connected to the additional capacitance element or floating diffusion region and used to discharge the photoelectric charge on the additional capacitive element and/or the floating diffusion region;
wherein the capacitance of the floating diffusion region is smaller than that of the photodiode;
the method comprising:
a step in which the photoelectric charge generated by the photodiode when it receives light is accumulated in the photodiode during the accumulation period; and
a step in which a first signal obtained by transferring part or all of the photoelectric charge accumulated in the photodiodes in all of the pixels to the floating diffusion region or a second signal obtained by transferring all of the photoelectric charge accumulated in the photodiodes in all of the pixels to the capacitance obtained by coupling the floating diffusion region and the additional capacitance element is output as the output of the pixels;
wherein, in the step of obtaining the first or second signal as the output of the pixels, the first or second signal is obtained for all of the pixels.

10. The method of claim 9, wherein, in the step of obtaining the first or second signal as the output of the pixels, the first or second signal is obtained corresponding to a switch used for selecting either the first signal or second signal.

11. The method of claim 9, wherein, in the step of obtaining the first or second signal as the output of the pixels, the first or second signal of the pixels of two adjacent rows is output during the same horizontal blanking period as the output of the pixels.

12. The method of claim 9, wherein, in the step of obtaining the first or second signal as the output of the pixels, the first or second signal is read twice from one the pixel, the obtained two first or second signals are added or their average is calculated, and the result is output as the output of the pixels.
